(19) United States
(12) Patent Application Publication
(10) Pub. No.: US 2021/0402653 A1
(43) Pub. Date: Dec. 30, 2021

(54) NANOIMPRINT MOLD AND MANUFACTURING METHOD THEREOF, AND PATTERN TRANSFER METHOD USING NANOIMPRINT MOLD

(71) Applicant: BOE TECHNOLOGY GROUP CO., LTD., Beijing (CN)

(72) Inventors: Zhao Kang, Beijing (CN); Kang Guo, Beijing (CN)

(73) Assignee: BOE TECHNOLOGY GROUP CO., LTD., Beijing (CN)

(21) Appl. No.: 16/769,341

(22) PCT Filed: Jul. 11, 2019
(86) PCT No.: PCT/CN2019/095574

§ 371 Date: Jun. 3, 2020

(51) Int. Cl. B29C 33/42; B29C 33/38; G03F 7/00; B82Y 40/00

(52) U.S. Cl. CPC B29C 33/424; B29C 33/3807; B82Y 40/00; G03F 7/0002; B29C 33/3842

(57) ABSTRACT

The nanoimprint mold (100) includes a base substrate (10). The base substrate (10) includes a main area (MA) and a secondary area (SA) surrounding the main area (MA). The main area (MA) includes a molding structure (16), and the molding structure (16) includes a plurality of first concave portions (18) and a plurality of first convex portions (20). The secondary area (SA) includes a grating structure (22), and the grating structure (22) includes a plurality of second concave portions (24) and a plurality of second convex portions (26). A height of at least one of the second convex portions (26) is larger than a height of at least one of the first convex portions (20). The nanoimprint mold (100), manufacturing method thereof, and pattern transfer method using nanoimprint mold (100) make the overflow of the nanoimprint resist in the secondary area (SA) of the nanoimprint mold (100) is significantly suppressed, and the topography of pattern in the secondary area (SA) of the nanoimprint mold (100) is significantly improved. Furthermore, the thickness of the resist layer in the adjacent areas will not be significantly increased. Accordingly, the defective area of the pattern of the resist layer, especially at the joint area between the two nanoimprinting positions, is significantly reduced.

### TECHNICAL FIELD

This disclosure relates to a nanoimprint technique, in particular, to a nanoimprint mold, a manufacturing method thereof, and a pattern transfer method using the nanoimprint mold.

### BACKGROUND

In recent years, semiconductor integrated circuits are becoming increasing finer and more integrated. Nanoimprint transfer method has gained wide attention as one of technologies for carrying out fine pattern formation at low cost. In this method, a mold having a same concave-convex pattern as that which is desired to be formed on a substrate is first stamped onto a resist film layer formed on a surface of a substrate, thereby transferring the predetermined pattern onto the substrate.

### BRIEF SUMMARY

One example of the present disclosure is a nanoimprint mold. The nanoimprint mold may include a base substrate. The base substrate may include a main area and a secondary area surrounding the main area. The main area may include a molding structure, which may include a plurality of first concave portions and a plurality of first convex portions. The secondary area may include a grating structure, which may include a plurality of second concave portions and a plurality of second convex portions. A height of at least one of the second convex portions is larger than a height of at least one of the first convex portions.

Another example of the present disclosure is a method of manufacturing a nanoimprint mold. The method may include forming a metal layer on a base substrate, the base substrate comprising a main area and a secondary area; forming a layer of first photoresist on the metal layer; forming a grating pattern of the first photoresist in the secondary area by an electron beam direct writing method; etching the metal layer through the grating pattern of the first photoresist to form a grating pattern of the metal layer in the secondary area; forming a layer of second photoresist on the exposed base substrate and the grating pattern of the metal layer; forming a grating pattern of the second photoresist on the base substrate and the grating pattern of the metal layer by an electron beam direct writing method; etching the base substrate through the grating pattern of the second photoresist; and removing the grating pattern of the second photoresist to form a molding structure in the main area and a grating structure in the secondary area. The molding structure comprises a plurality of first concave portions and a plurality of first convex portions, the grating structure comprises a plurality of second concave portions and a plurality of second convex portions. A height of at least one of the second convex portions is larger than a height of at least one of the first convex portions.

Another example of the present disclosure is a pattern transfer method. The pattern transfer method includes forming a first nanostructure in a first area of a substrate and forming a second nanostructure in a second area of the substrate using the nanoimprint mold according to one embodiment of the present disclosure.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows a schematic top view of a nanoimprint mold in the related art;

FIGS. 2a-2e show a schematic illustration of forming a pattern of resist layer on a substrate by a nanoimprint mold in the related art;

FIG. 3a shows a schematic top view of a nanoimprint mold according to some embodiments of the present disclosure;

FIG. 3b shows a schematic cross-section view of a nanoimprint mold along line BB′ in FIG. 3a;

FIGS. 4a-4i show schematic illustration of a method of manufacturing a nanoimprint mold according to some embodiments of the present disclosure;

FIGS. 5a-5f show schematic illustration of a pattern transfer method according to some embodiments of the present disclosure;

FIG. 6 shows schematic illustration of forming a plurality of nanostructures on a substrate according to some embodiments of the present disclosure; and

FIG. 7 shows schematic illustration of forming two adjacent patterns of embossing adhesive on a substrate according to some embodiments of the present disclosure.

### DETAILED DESCRIPTION

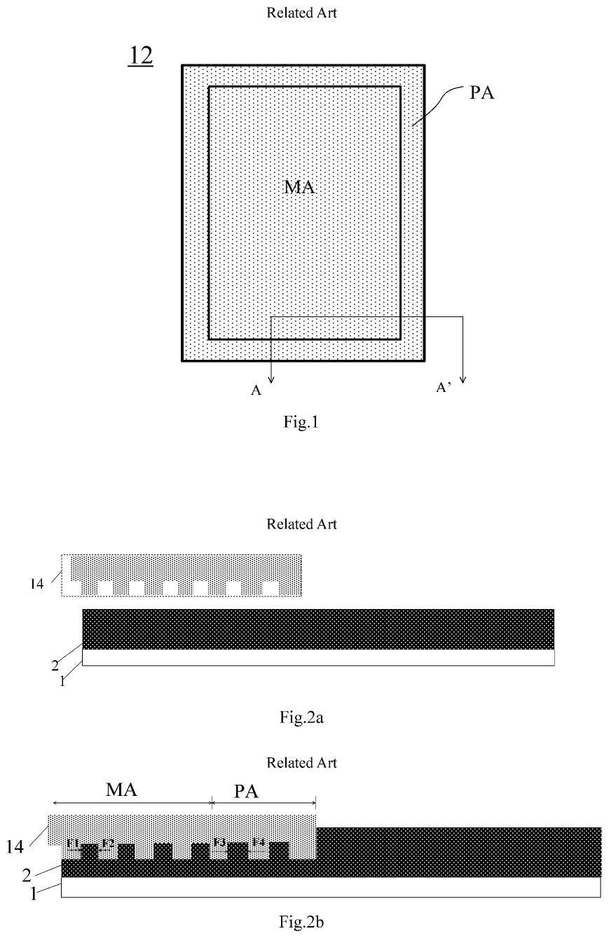

The present disclosure will be described in further detail with reference to the accompanying drawings and embodiments in order to provide a better understanding by those skilled in the art of the technical solutions of the present disclosure. Throughout the description of the disclosure, reference is made to FIGS. 1-7. When referring to the figures, like structures and elements shown throughout are indicated with like reference numerals.

In this specification, the terms “first,” “second,” etc. may be added as prefixes. These prefixes, however, are only added in order to distinguish the terms and do not have specific meaning such as order and relative merits. In the description of the present disclosure, the meaning of “plural” is two or more unless otherwise specifically defined.

In the description of the specification, references made to the term “some embodiments,” “one embodiment,” “exemplary embodiments,” “example,” “specific example,” “some examples” and the like are intended to refer that specific features, structures, materials or characteristics described in connection with the embodiment or example are included in at least some embodiments or examples of the present disclosure. The schematic expression of the terms does not necessarily refer to the same embodiment or example. Moreover, the specific features, structures, materials or characteristics described may be included in any suitable manner in any one or more embodiments or examples. A number modified by “about” herein means that the number can vary by 10% thereof.

The nanoimprint mold usually has a small size. To form a nanostructure in a large area, the nanoimprint mold first needs to be repeatedly stamped on the resist film layer on the surface of the substrate to form a pattern of the resist film layer. Then, the pattern of the resist film layer is used as a mask during the subsequent steps such as etching to form the nanostructure. Thus, the quality of the pattern of the resist film layer is very important for forming a uniform nanostructure on the substrate in the subsequent steps. However, during the nanoimprinting process, due to unbalanced forces applied on the resist of the resist film layer by the periphery area of the nanoimprint mold, the excess resist in the periphery area of the nanoimprint mold may overflows outward quickly, thereby forming defective areas in the pattern of the resist film layer.

FIG. 1 shows a schematic illustration of a nanoimprint mold in the related art. As shown in FIG. 1, the nanoimprint mold 12 includes a main area (MA) and a periphery area (PA) surrounding the main area.

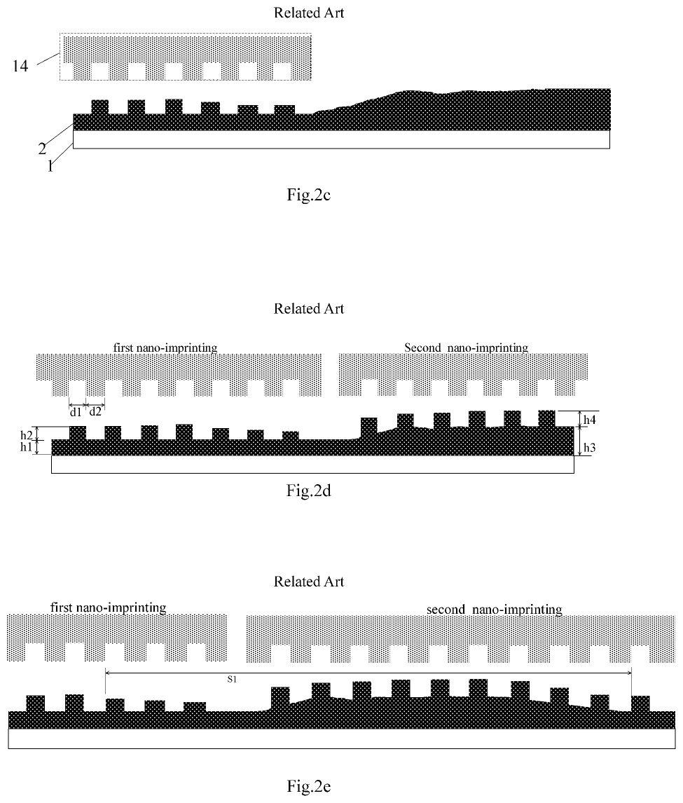

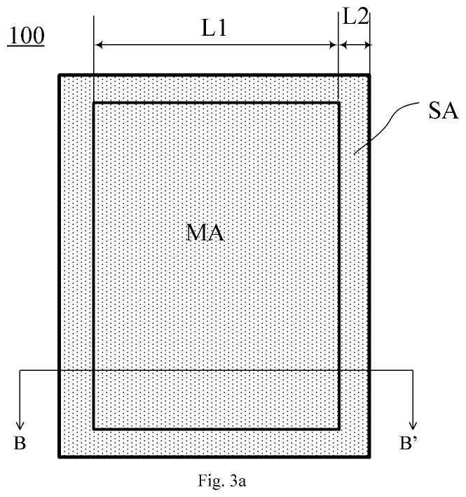

FIGS. 2a-2e show a schematic illustration of forming a pattern of a resist layer on a substrate using a nanoimprint mold in the related art. FIG. 2a also illustrates a cross-sectional view of a part of the nanoimprint mold 14 in FIG. 1 along line AA′. During the nanoimprinting process, a resist layer 2 is first formed on a substrate 1. Then the nanoimprint mold is pressed onto the resist layer. As shown in FIG. 2b, for the convex portion of the resist in the area corresponding to the MA of the nanoimprint mold, the forces F1 and F2 acting from both sides of the convex portion of the resist are substantially the same. However, for the convex portion of the resist in the area corresponding to the PA of the nanoimprint mold, the forces F3 and F4 acting from both sides of the convex portion of the resist are not the same. That is, the force F3 pushing outward is larger than the force F4 pushing inward. Consequently, the excess resist overflows outward to an adjacent area, thereby resulting in a thicker layer of resist in the adjacent area for the second nanoimprinting, as shown in FIG. 2c. Furthermore, due to unbalanced forces on the convex portions of the resist in the area corresponding to the PA of the nanoimprint mold, it is very difficult to form a completely uniform nanoimprint pattern. That is, the heights of the convex portions of the resist in the area corresponding to the PA of the nanoimprint mold are lower than the heights of the convex portions of the resist in the area corresponding to MA of the nanoimprint mold, as shown in FIG. 2c.

FIG. 2d shows a schematic cross-sectional view of two adjacent patterns of the resist layer formed by two nanoimprinting processes on a substrate using a nanoimprint mold in the related art. As shown in FIG. 2d, for the pattern of the resist layer formed by the first nanoimprinting on the left, the heights of the convex portions in the area corresponding to the PA of the nanoimprint mold are shorter than those in the area corresponding to the MA of the nanoimprint mold. Furthermore, the base layer of the pattern of the resist layer formed by the second nanoimprinting on the right is thicker. For example, as shown in FIG. 2d, the thickness of the base layer for the second pattern of the resist layer, h3, is much higher than the thickness of the base layer for the first pattern of the resist layer, h1. Thus, the convex portions of the first pattern of the resist layer in the area corresponding to the PA of the nanoimprint mold and the convex portions of the second pattern of the resist layer having a thicker base layer constitute defective area of the two adjacent nanostructures, as shown in FIG. 2e. The defective area is relatively wide, and may have a width, S1, of at least 15 μm.

FIG. 3a shows a top view of a nanoimprint mold 100 according to one embodiment of the present disclosure. As shown in FIG. 3a, the nanoimprint mold 100 includes a main area (MA) and a secondary area (SA) surrounding the main area. The main area (MA) may have a width of L1, and the secondary area (SA) may have a width of L2, where L1>L2. In an embodiment, L1 may be in a range of about 2 inch to about 12 inch, and L2 may be in a range of about 0.3 μm to about 2.5 μm.

FIG. 3b shows a schematic cross-section view of the nanoimprint mold in FIG. 3a along line BB′. As shown in FIG. 3b, the nanoimprint mold may include a base substrate 10. The base substrate includes a main area (MA) and a secondary area (SA) surrounding the main area. The main area includes a molding structure 16, and the molding structure 16 includes a plurality of first concave portions 18 and a plurality of first convex portions 20. The secondary area includes a grating structure 22, and the grating structure 22 includes a plurality of second concave portions 24 and a plurality of second convex portions 26. A height, H2, of at least one of the second convex portions is larger than a height, H1, of at least one of the first convex portions. In some embodiment, as shown in FIG. 3b, each of the plurality of first convex portions 20 has a substantially same height, H1. Each of the plurality of second convex portions 26 has a substantially same height, H2. The height H2 of the plurality of second convex portions is larger than the height H1 of the plurality of first convex portions.

In some embodiments, the height, H2, of at least one of the second convex portions is in a range of about 120 nm to about 550 nm, preferably about 160 nm to about 420 nm. In some embodiments, the height, H1, of at least one of the first convex portions is in a range of about 60 nm to about 300 nm, preferably about 120 nm to about 200 nm. A width of the grating structure, that is, a width L2 of the SA, may be in a range of about 0.3 μm to about 2.5 μm, preferably about 0.5 μm to about 1.5 μm. In one embodiment, a width of the grating structure is about 1 μm.

In some embodiments, as shown in FIG. 3b, each of the second convex portions comprises a bottom portion 262 and a top portion 264. The top portion 264 and the bottom portion 262 may be made of different materials. The bottom portion 262 of each of the second convex portions, the base substrate, and the first convex portions may be made of a same material. In one embodiment, the bottom portion 262 of each of the second convex portions, the base substrate 10, and the first convex portions 20 may be made of a first metal such as Ni, a first inorganic material such as Si, quartz, or glass, or a first polymer such as polydimethylsiloxane. In some embodiments, the top portion of each of the second convex portions 264 is made of a second metal such as Mo or Ti or a second inorganic material such as SiNₓ or SiOₓ.

The plurality of second convex portions 26 may have a same width or different widths. In some embodiments, a width of each of the second convex portions is in a range of about 50 nm to about 100 nm. A width of each second concave portion may be same or different. In some embodiments, a width of each of the second concave portions is in a range of about 100 nm to about 200 nm. In some embodiments, a width of each of the first convex portions is in a range of about 150 nm to about 200 nm, and a width of each of the first concave portions is in a range of about 170 nm to about 220 nm. Herein a width of a feature refers to a length of the feature measured in a direction parallel to the top large surface of the base substrate of the nanoimprint mold, as shown in FIG. 2b.

According to some embodiments of the present disclosure, by adding a grating structure at the secondary area of the nanoimprint mold, during the nanoimprinting, the forces F3 and F4 acting from both sides of the convex portion of the resist in the area corresponding to the PA of the nanoimprint mold in the related art are substantially the same. As a result, the overflow of the nanoimprint resist in the area of substrate corresponding to the PA of the nanoimprint mold in the related art is significantly suppressed, and the topography of pattern in the area of the substrate corresponding to the PA of the nanoimprint mold is significantly improved. Furthermore, the thickness of the resist layer in the adjacent areas will not be significantly increased. Accordingly, the defective area of the pattern of the resist layer, especially at the joint area between the two nanoimprinting positions, is significantly reduced.

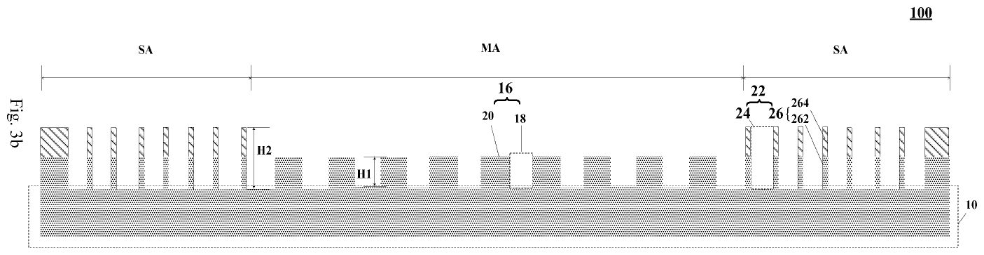

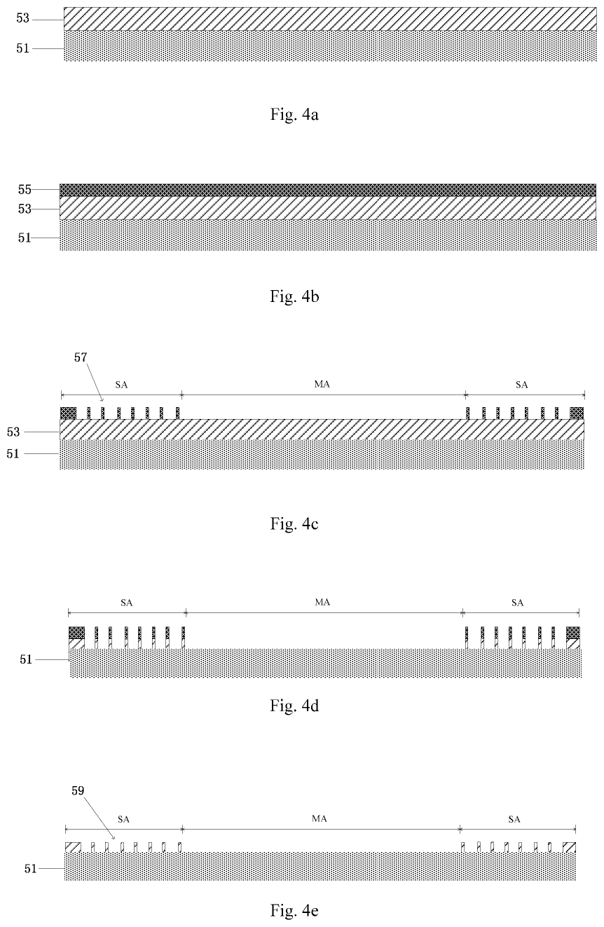

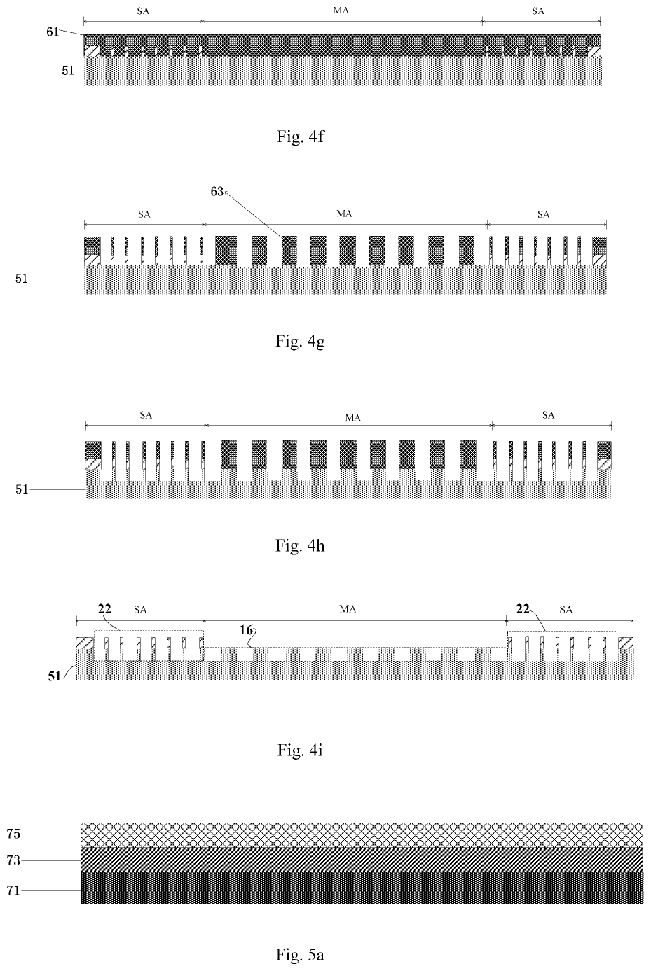

FIGS. 4a-4i show schematic illustration of a method of manufacturing a nanoimprint mold according to some embodiments of the present disclosure. In some embodiments, as shown in FIG. 4a, the manufacturing method includes forming a metal layer 53 on a base substrate 51. The base substrate 51 may include a main area for forming a molding structure thereon and a secondary area for forming a grating structure thereon. The secondary area is at the periphery of the main area and surrounds the main area. The metal layer may be formed of a metal such as Mo or Ni, and may be formed on the base substrate by an evaporation deposition technique. The base substrate may be formed of a first metal such as Ni, a first inorganic material such as Si, quartz, or glass, or a first polymer such as polydimethylsiloxane.

In some embodiments, as shown in FIG. 4b, after forming the metal layer, the manufacturing method may further include forming a layer of first photoresist 55 on the metal layer 53. The composition of the first photoresist may include a phenolic resin, a sensitizer, propylene glycol methyl ether acetate, and other additives. In one embodiment, a content of the phenolic resin, the sensitizer, and the propylene glycol methyl ether acetate in the first photoresist may be about 15 wt % to about 30 wt %, about 2 wt % to about 10 wt %, and about 50 wt % to about 70 wt % of the composition of the first photoresist, respectively. The layer of first photoresist 55 may be formed on the metal layer by a coating technique such as spin coating.

In some embodiments, as shown in FIG. 4c, after forming the layer of first photoresist on the metal layer 53, the manufacturing method may further include forming a grating pattern of the first photoresist 57 in the secondary area, for example, by an electron beam direct writing method, a laser direct writing method, or a laser interference method. The grating pattern of the first photoresist includes a plurality of convex portions of the first photoresist distributed at intervals on the metal layer. Among them, the electron beam direct writing method can form the plurality of convex portions each having a width of several nanometers or more. The laser direct writing method and the laser interference method can form the plurality of convex portions each having a width of several hundred nanometers or more. The grating pattern of the first photoresist 57 will be used as a mask for etching the underneath metal layer 53 to form the grating structure during subsequent steps.

In some embodiments, as shown in FIGS. 4d and 4e, after forming the grating pattern of the first photoresist 57, the manufacturing method may further include etching the metal layer through the grating pattern of the first photoresist as a mask to form a grating pattern of the metal layer 59 in the secondary area. Etching the metal layer may be performed by a dry etching technique. As shown in FIG. 4d, the metal layer in the main area is completely removed by the etching process since there is no grating pattern of the first photoresist 57 as a mask in the main area. The grating pattern of the metal layer 53 includes a plurality of convex portions of the metal layer. Each of the plurality of convex portions of the metal layer corresponds to one of the plurality of convex portions of the first photoresist. After etching the metal layer, the plurality of convex portions of the first photoresist is removed by, for example, a stripping technique or an ashing technique, as shown in FIG. 4e. Accordingly, the grating pattern of the metal layer 59 in the secondary area is formed.

In some embodiments, as shown in FIG. 4f, after forming the grating pattern of the metal layer 59 in the secondary area, the manufacturing method may further include forming a layer of second photoresist 61 on the exposed base substrate and the grating pattern of the metal layer 59. The layer of second photoresist 61 covers the exposed base substrate in the main area and the grating pattern of the metal layer in the secondary area. A thickness of the layer of the second photoresist 61 is larger than a height of the plurality of convex portions of the grating pattern of the metal layer. The composition of the second photoresist may be the same or similar as the composition of the first photoresist. The composition of the second photoresist may also be different from the composition of the first photoresist, of course.

In some embodiments, as shown in FIG. 4g, after forming the layer of second photoresist, the manufacturing method may further include forming a grating pattern of the second photoresist 63 on the base substrate and on the grating pattern of the metal layer by an electron beam direct writing method, a laser direct writing method, or a laser interference method. The grating pattern of the second photoresist 63 includes a plurality of convex portions of the second photoresist in the main area, which will be used as a mask to form the molding structure in the main area via etching in subsequent steps. The grating pattern of the second photoresist also includes a plurality of convex portions in the secondary area, which is on top of the plurality of convex portions of the metal layer respectively. The plurality of convex portions of the second photoresist in the secondary area will also be used as a mask to form the grating structure in the secondary area via etching in subsequent steps.

In some embodiments, as shown in FIG. 4h, after forming the grating pattern of the second photoresist 63, the manufacturing method may further include etching the base substrate through the grating pattern of the second photoresist 63 to form a molding structure 16 in the main area and a grating structure 22 in the secondary area. That is, the base substrate is etched with the grating pattern of the second photoresist as a mask. In one embodiment, the base substrate is etched by a dry etching technique.

In some embodiments, as shown in FIG. 4i, after etching the base substrate, the manufacturing method may further including removing the grating pattern of the second photoresist 63 on the molding structure in the main area and the grating structure in the secondary area. Removing the grating pattern of the second photoresist may be performed, for example, by a stripping technique or an ashing technique. The molding structure 16 comprises a plurality of first concave portions and a plurality of first convex portions. The grating structure 22 comprises a plurality of second concave portions and a plurality of second convex portions. Each of the second convex portions comprises a bottom portion and a top portion. The bottom portion is made of the same material as the base substrate. A height of at least one of the second convex portions, which is a sum of a height of the bottom portion and a height of the top portion, in the secondary area is larger than a height of at least one of the first convex portions in the main area.

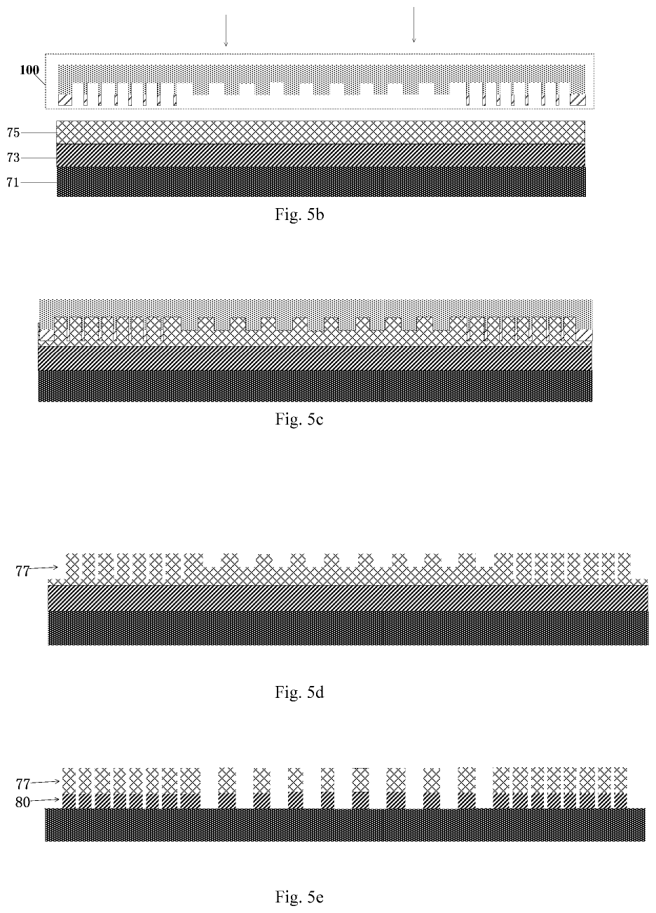

FIGS. 5a-5f show schematic illustration of a pattern transfer method according to some embodiments of the present disclosure. In some embodiments, the pattern transfer method may include forming a first nanostructure in a first area of a substrate using the nanoimprint mold according to one embodiment of the present disclosure.

In some embodiments, as shown in FIG. 5a, the pattern transfer method includes forming a metal layer 73 and a layer of embossing adhesive 75 sequentially on a substrate 71. The substrate may be made of a glass. The metal layer may include a metal such as Al. In one embodiment, the embossing adhesive is an acrylic-based resin or an epoxy-based resin. The embossing adhesive may include a photoinitiator and other additives.

In some embodiments, as shown in FIGS. 5b and 5c, the pattern transfer method further includes aligning and pressing the nanoimprint mold 100 according to one embodiment of the present disclosure into the layer of embossing adhesive 75 to form a pattern of the embossing adhesive 77 in a first area of the substrate. In some embodiments, a thickness of the layer of embossing adhesive is larger than a height of any of the second convex portions of the grating structure of the nanoimprint mold.

In some embodiments, as shown in FIG. 5d, the pattern transfer method further includes removing or separating the nanoimprint mold from the substrate to form a pattern of embossing adhesive 77 on the metal layer 73 in the first area of the substrate. The pattern of embossing adhesive 77 includes a plurality of convex portions and a plurality of concave portions. A thin layer of the embossing adhesive is still present at the bottom of the concave portions of the embossing adhesive on the metal layer. That is, the underneath metal layer is not exposed to air even in the concave portions of the embossing adhesive.

In some embodiments, as shown in FIG. 5e, after separating the nanoimprint mold from the substrate, the pattern transfer method further includes etching processes. In one embodiment, the etching processes include, using the pattern of the embossed adhesive 77 as a mask, a first etching of the embossing adhesive in an inductively coupled plasma (ICP) atmosphere to remove the thin layer of the embossing adhesive at the bottom of the concave portions of the embossing adhesive on the metal layer. The conditions for the first etching of the embossing adhesive in an inductively coupled plasma (ICP) atmosphere may include Oxygen (O₂) with a pressure of 1.0˜10.0 mT, a temperature of 40˜100° C., and a power of 200˜1500 W. As a result, the underneath metal layer is exposed in the concave portions of the embossing adhesive. Then, using the pattern of embossing adhesive as a mask, a second etching is performed on the underneath metal layer to form a first nanostructure 80 of the metal layer. The second etching of the metal layer may be performed, for example, by an ICP technique. The conditions for the second etching of the metal layer in an inductively coupled plasma (ICP) atmosphere may include Cl₂, Cl₃, CH₄, and N₂, with a pressure of 1.0˜15.0 mT, a temperature of 40˜100° C., and a power of 300˜2500 W.

In some embodiments, as shown in FIG. 5f, after etching the metal layer, the pattern transfer method further includes removing the pattern of embossing adhesive 77 on the first nanostructure 80, thereby obtaining the first nanostructure 80 in the first area of the substrate. The pattern of embossing adhesive 77 may be removed, for example, by a stripping technique or an ashing technique. As shown in FIG. 5f, all the convex portions of the first nanostructure 80 in the area corresponding to the main area (MA) of the nanoimprint mold have a substantially same height, and accordingly are very uniform. There is little or no defective area in the area corresponding to the main area (MA) of the nanoimprint mold.

In some embodiment, the pattern transfer method further includes forming a second nanostructure in a second area of the substrate using the nanoimprint mold according to some embodiments of the present disclosure. The second area is adjacent to the first area. The distance between the first area and the second area may be in a range of 50 nm and 15 μm, preferably in a range of 100 nm to 10 μm. The process of forming the second nanostructure may be similar as the process of forming the first nanostructure as discussed above, and is not repeated herein. Similarly, the nanoimprinting process as discussed above may be repeated many times to form a plurality of nanostructures on the substrate.

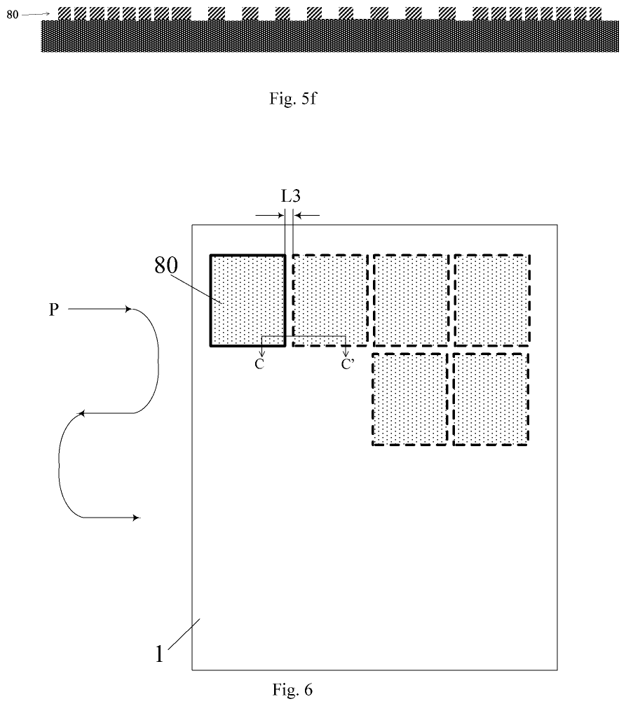

FIG. 6 shows schematic illustration of forming a plurality of nanostructures on a substrate according to one embodiment of the present disclosure. In some embodiments, to form an integral nanostructure on a large area of the substrate, the process of forming the first nanostructure is repeatedly performed to form a plurality of nanostructures onto different areas of the substrate. The plurality of nanostructures may be adjoined with one another or has a short distance such as L3 among them, as shown in FIG. 6. L3 may range from about 100 nm to 10 um. P is the moving route of the nanoimprint mold on the substrate 1 during the nanoimprinting processes. P may have a S curve or other type. Accordingly, the plurality of nanostructures may constitute an integral nanostructure in a large area of the substrate.

According to some embodiments of the present disclosure, due to the presence of the grating structure in the secondary area of the nanoimprint mold, the embossing adhesive at the edges of the main area in the first area of the substrate experiences the same forces pushing inward and outward. Thus, overflow of the excess embossing adhesive in the first area of the substrate during the first nanoimprinting is significantly suppressed. As such, the pattern of the embossing adhesive in the main area, especially at the edges of the main area, after the first nanoimprinting is uniform. Furthermore, the thickness of the embossing adhesive in an adjacent area to the first area for the second nanoimprinting is not increased significantly. Thus, the defective area between the two adjacent patterns of the embossing adhesive is significantly reduced. As a result, the defective area between the two adjacent nanostructures formed using the two adjacent patterns of the embossing adhesive as a mask is significantly reduced.

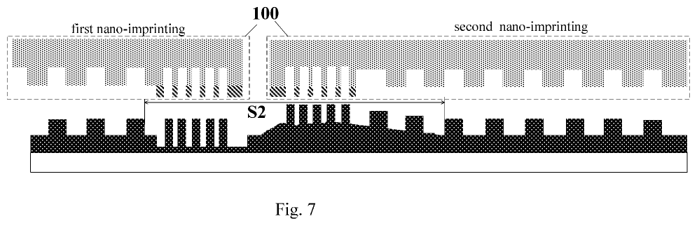

FIG. 7 shows schematic illustration of cross-sectional view of two adjacent patterns of the embossing adhesive formed by the pattern transfer method according to one embodiment of the present disclosure. FIG. 7 may be a schematic cross-section view along line CC′ in FIG. 6. As shown in FIG. 7, the convex portions in the main area of the first pattern of the embossing adhesive in the first area are very uniform. Due to the suppression of the overflow of the embossing adhesive from the first area to the adjacent area during the first nanoimprinting, the area of the convex portions of the second pattern of embossing adhesive having a thicker base layer is significantly reduced. As shown in FIG. 7, the width of the defective area of the two adjacent patterns of the embossing adhesive is significantly reduced. In one embodiment, the defective area may have a width, S2, in a range of 5 μm to 8 μm. In one embodiment, S2 may be about 5 μm.

Another example of the present disclosure is a nanostructure produced by the pattern transfer method according to one embodiment of the present disclosure. Another example of the present disclosure is a display panel comprising the nanostructure formed according to one embodiment of the present disclosure.

The principle and the embodiment of the disclosure are set forth in the specification. The description of the embodiments of the present disclosure is only used to help understand the method of the present disclosure and the core idea thereof. Meanwhile, for a person of ordinary skill in the art, the disclosure relates to the scope of the disclosure, and the embodiment is not limited to the specific combination of the technical features, and also should covered other embodiments which are formed by combining the technical features or the equivalent features of the technical features without departing from the inventive concept. For example, embodiments may be obtained by replacing the features described above as disclosed in this disclosure (but not limited to) with similar features.

1. A nanoimprint mold, comprising:
a base substrate, the base substrate comprising a main area and a secondary area surrounding the main area;
wherein the main area comprises a molding structure, and the molding structure comprises a plurality of first concave portions and a plurality of first convex portions, the secondary area comprises a grating structure, the grating structure comprises a plurality of second concave portions and a plurality of second convex portions, and
a height of at least one of the plurality of second convex portions is larger than a height of at least one of the plurality of first convex portions.

2. The nanoimprint mold of claim 1, wherein the height of at least one of the plurality of second convex portions is in a range of about 160 nm to about 420 nm.

3. The nanoimprint mold of claim 1, wherein the height of at least one of the plurality of first convex portions is in a range of about 120 nm to about 200 nm and/or a width of the grating structure is in a range of about 0.5 μm to about 1.5 μm.

4. (canceled)

5. The nanoimprint mold of claim 1, wherein each of the plurality of second convex portions comprises a bottom portion and a top portion, the top portion and the bottom portion being made of different materials, and the bottom portion of each of the plurality of second convex portions, the base substrate, and the plurality of first convex portions are made of a same material.

6. The nanoimprint mold of claim 5, wherein the bottom portion of each of the plurality of second convex portions, the base substrate, and the plurality of first convex portions are made of a first metal, a first inorganic material, or a first polymer.

7. The nanoimprint mold of claim 6, wherein the first metal is Ni; the first inorganic material is Si, quartz, or glass; and the first polymer is polydimethylsiloxane.

8. The nanoimprint mold of claim 5, wherein the top portion of each of the plurality of second convex portions is made of a second metal or a second inorganic material.

9. The nanoimprint mold of claim 8, wherein the second metal is Mo or Ti, and the second inorganic material is SiNₓ or SiOₓ.

10. The nanoimprint mold of claim 1, wherein a width of each of the plurality of second convex portions is in a range of about 50 nm to about 100 nm, and a width of each of the plurality of second concave portions is in a range of about 100 nm to about 200 nm.

11. The nanoimprint mold of claim 1, wherein a width of each of the plurality of first convex portions is in a range of about 150 nm to about 200 nm, and a width of each of the plurality of first concave portions is in a range of about 170 nm to about 220 nm.

12. A method of manufacturing a nanoimprint mold, comprising:
forming a metal layer on a base substrate, the base substrate comprising a main area and a secondary area;
forming a layer of first photoresist on the metal layer;
forming a grating pattern of the first photoresist in the secondary area by an electron beam direct writing method;
etching the metal layer through the grating pattern of the first photoresist to form a grating pattern of the metal layer in the secondary area;
forming a layer of second photoresist on the exposed base substrate and the grating pattern of the metal layer;
forming a grating pattern of the second photoresist on the base substrate and the grating pattern of the metal layer by an electron beam direct writing method;
etching the base substrate through the grating pattern of the second photoresist; and
removing the grating pattern of the second photoresist to form a molding structure in the main area and a grating structure in the secondary area;
wherein the molding structure comprises a plurality of first concave portions and a plurality of first convex portions, the grating structure comprises a plurality of second concave portions and a plurality of second convex portions, and a height of at least one of the plurality of second convex portions is larger than a height of at least one of the plurality of first convex portions.

13. The method of claim 12, wherein each of the plurality of second convex portions comprises a bottom portion and a top portion, the top portion and the bottom portion being made of different materials, and the bottom portion of each of the plurality of second convex portions, the base substrate, and the plurality of first convex portions are made of a same material.

14. A pattern transfer method, comprising:
forming a first nanostructure in a first area of a substrate using the nanoimprint mold of claim 1.

15. The pattern transfer method of claim 14, wherein forming the first nanostructure in the first area of the substrate comprises:
forming a metal layer on the substrate;
forming a layer of embossing adhesive on the metal layer;
pressing the nanoprint mold onto the layer of embossing adhesive in the first area of the substrate;
removing the nanoimprint mold to form a pattern of embossing adhesive on the metal layer in the first area of the substrate;
etching the metal layer through the pattern of embossing adhesive; and
removing the pattern of embossing adhesive to obtain the first nanostructure in the first area of the substrate.

16. The pattern transfer method of claim 15, wherein the height of at least one of the plurality of second convex portions of the nanoimprint mold is less than or equal to a thickness of the layer of embossing adhesive.

17. The pattern transfer method of claim 15, wherein removing the pattern of embossing adhesive is performed by a stripping process or an ashing process.

18. The pattern transfer method of claim 14, further comprising:
forming a second nanostructure in a second area of the substrate using the nanoimprint mold;
wherein an area of the first nanostructure corresponding to the secondary area of the nanoimprint mold overlaps or adjoins an area of the second nanostructure corresponding to the secondary area of the nanoimprint mold.

19. The pattern transfer method of claim 15, wherein the first nanostructure comprises a plurality of third concave portions and a plurality of third convex portions on the substrate;
the second nanostructure comprises a plurality of fourth concave portions and a plurality of fourth convex portions on the substrate; and
the plurality of third convex portions and the plurality of fourth convex portions have a substantially same height.

20. A nanostructure produced by the pattern transfer method of claim 14.

21. A display panel comprising the nanostructure of claim 20.
